(19) United States
(12) Patent Application Publication
(10) Pub. No.: US 2005/0047100 A1
(43) Pub. Date: Mar. 3, 2005

(54) Plasma display device and standoff of chassis base therefor

(76) Inventor: Doo-Young Kim, Suwon-si (KR)

Correspondence Address: CHRISTIE, PARKER & HALE, LLP, PO BOX 7068, PASADENA, CA, 91109-7068, US

(21) Appl. No.: 10/925,129

(22) Filed: Aug. 23, 2004

(30) Foreign Application Priority Data
Sep. 2, 2003 (KR) 2003-0061183
Jul. 27, 2004 (KR) 2004-0058583

(51) Int. Cl. H01R 13/648; H05K 5/00; H05K 5/04; H01R 4/66; H05K 5/06

(52) U.S. Cl. 361/758

(57) ABSTRACT

A plasma display device includes a plasma display panel for displaying the desired images, a chassis base for supporting the plasma display panel with a plurality of combination holes, and standoffs installed at the chassis base. The respective standoffs have a cylindrical portion with an outer diameter, a transformed portion connected to the cylindrical portion with an outer diameter substantially identical with the outer diameter of the cylindrical portion and inserted into the combination hole together with the cylindrical portion, and flanges connected to the transformed portion, and press-fitted to the surfaces of the chassis base while interposing the combination hole.

### CROSS-REFERENCE TO RELATED APPLICATIONS

This application claims priority to and the benefit of Korean Patent Application No. 2003-0061183 filed on Sep. 2, 2003, and Korean Patent Application No. 2004-0058583 filed on Jul. 27, 2004, both applications filed in the Korean Intellectual Property Office, the entire content of which is incorporated herein by reference.

### BACKGROUND OF THE INVENTION

(a) Field of the Invention

The present invention relates to a plasma display device, and in particular, to a chassis base for supporting a plasma display panel (referred to hereinafter as the “PDP”).

(b) Description of Related Art

Generally, a plasma display device is a device which displays desired images based on a gas discharge phenomenon. Because the plasma display device exhibits excellent display capacity, brightness, contrast and viewing angle, and further because it is wide-screened, light-weight and thin, plasma display devices have become increasingly popular.

The conventional plasma display device may include a PDP for displaying the desired images, a chassis base for supporting the PDP, a plurality of driving modules installed at the chassis base opposite to the PDP with various sorts of driving circuits, and a case surrounding the PDP, the chassis base and the driving modules to protect them.

The PDP is structured such that two glass substrates are combined with each other in a vacuum tight manner, and electrodes and a phosphor layer are formed therein to display the desired images based on the gas discharge.

The chassis base supports the panel, and uniformly distributes and dissipates the high heat generated from the panel. Therefore, the chassis base is formed with aluminum having high thermal conductivity and rigidity.

A thermal conductive medium, such as a heat dissipation sheet, may be installed between the chassis base and the PDP to dissipate heat.

A plurality of standoffs are installed at the chassis base to fix the driving modules, such as a printed circuit board and other structural components.

With respect to the plasma display device, the PDP is formed with glass substrates. Therefore, as it becomes wide-screened, its weight is increased, and the chassis base for supporting it should be rigid with a reasonable strength.

The chassis base is formed mainly through die casting or press processing. In the case of die casting, the resulting chassis base is more reliable in its strength compared to a chassis that is press processed. Because the surface of the chassis base is not even, it is difficult to install a thermal conduction sheet on it tightly. When die casting is applied to a wide-screened panel, the weight of the panel is greatly increased. Therefore, in the case of a small screen of 42 inches or less, the chassis base is made mainly by die casting and in the case of a wide screen of 50 inches or more, a press-processed chassis base is mainly used.

When the chassis base is formed through die casting, standoffs are incorporated directly into the chassis base, and when it is formed through press processing, separate standoffs are forcefully fitted to an aluminum-based plate.

FIG. 7 illustrates a prior art standoff 4 forcefully fitted to the chassis base 2.

The standoff 4 has a cylindrical portion 5 with an outer diameter identical with or smaller than the combination hole 3 formed at the chassis base 2, and a saw-toothed portion 8 formed on the outer circumference of the cylindrical portion 5 with a plurality of saw teeth.

A fixation groove 7 is formed between the cylindrical portion 5 and the saw-toothed portion 8, and the end of the cylindrical portion 5 is formed with an inclined side 6.

When the standoff 4 is partially inserted into the chassis base 2 by forcefully fitting it through the combination hole 3 from the inclined side thereof 6, the inner circumference 3a of the combination hole 3 deformed by the saw-toothed portion 8 is partially put into the fixation groove 7 such that the standoff 4 is rigidly fixed to the chassis base 2.

The standoffs 4 do not have any problems supporting the printed circuit board fixed to the chassis base 2 or other structural components under the application of a dead load. However, under the application of a live load, the standoffs do not reliably support the chassis base.

Accordingly, in order to give the standoffs 4 enough supporting power to endure a live load, the fixation of the standoffs to the chassis base 2 may be reinforced using a separate fixture.

However, in this case, the combination-related processing steps and the number of relevant parts are increased, resulting in deteriorated productivity and increased production cost.

### SUMMARY OF THE INVENTION

In accordance with the present invention a plasma display device is provided which has standoffs with a supporting power enough to endure the live load.

According to one aspect of the present invention, the plasma display device includes a PDP for displaying the desired images, a chassis base for supporting the plasma display panel with a plurality of combination holes, and standoffs installed at the chassis base. The respective standoffs have a cylindrical portion with an outer diameter, a transformed portion connected to the cylindrical portion with an outer diameter substantially identical with the outer diameter of the cylindrical portion and inserted into the combination hole together with the cylindrical portion, and flanges connected to the transformed portion, and press-fitted to the surfaces of the chassis base while interposing the combination hole.

The flanges have a main flange and a subsidiary flange facing each other with an outer diameter larger than the outer diameter of the cylindrical portion and the transformed portion, and press-fitted to the chassis base while interposing the chassis base.

A reinforcing member may be placed in the combination hole between the flanges with an outer diameter substantially identical with the inner diameter of the combination hole.

A plurality of fixation protrusions may be formed on the main flange to prevent the rotation of the standoff fitted to the chassis base. The fixation protrusion may be tapered with a sharp end.

A pressurization member may be formed on the surface of the standoff facing the inner circumference of the combination hole to prevent the rotation of the standoff fitted to the chassis base. The pressurization member may be formed with a saw-toothed shape.

According to another aspect of the present invention, the standoff may includes a cylindrical portion with an outer diameter, an inclined portion connected to the cylindrical portion with an outer diameter larger than the outer diameter of the cylindrical portion, and a flange portion connected to the inclined portion with an outer diameter larger than the outer diameter of the inclined portion.

A reinforcing portion may be formed between the inclined portion and the flange portion with a large outer diameter larger than the outer diameter of the cylindrical portion.

A plurality of fixation protrusions may be formed on the flange portion with a sharp end.

Saw teeth may be formed around the inclined portion with a predetermined pattern while proceeding along the longitudinal direction of the standoff.

A pressurization portion may be formed between the inclined portion and the flange portion with a saw-toothed outer circumference.

### BRIEF DESCRIPTION OF THE DRAWINGS

FIG. 1 is an exploded perspective view of a plasma display device with a chassis base and standoffs according to a first embodiment of the present invention.

FIG. 2 is a partial exploded perspective view of the chassis base and the standoff for the plasma display device according to the first embodiment of the present invention.

FIGS. 3A and 3B are partial sectional views of the standoff fitted to the chassis base for the plasma display device according to the first embodiment of the present invention.

FIGS. 4A and 4B are partial sectional views of a standoff fitted to a chassis base for a plasma display device according to a second embodiment of the present invention.

FIGS. 5A and 5B are partial sectional views of a standoff fitted to a chassis base for a plasma display device according to a third embodiment of the present invention.

FIGS. 6A, 6B, 6C and 6D are partial sectional views of a standoff fitted to a chassis base for a plasma display device according to a fourth embodiment of the present invention.

FIG. 7 is a partial amplified sectional view of a standoff and a chassis base for a plasma display device according to the prior art.

### DETAILED DESCRIPTION

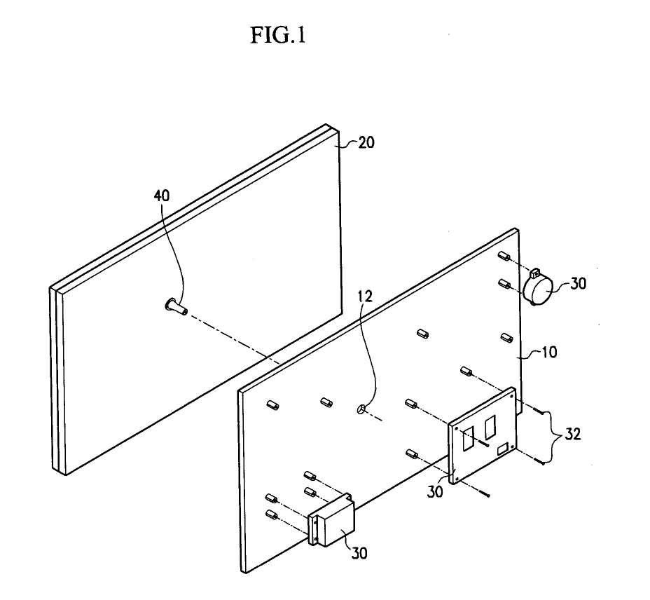

As shown in FIG. 1, the plasma display device includes a PDP 20 for displaying the desired images, a chassis base 10 for supporting the PDP 20 with a plurality of combination holes 12, and one or more driving modules 30 mounted at the chassis base 10 opposite to the panel 20 with a circuit for driving the PDP 20.

A standoff 40 is fitted to a respective combination hole 12 to fix a printed circuit board and/or other structural components (for example, a wall hanger, a guide stand, or a package) belonging to the driving module 30.

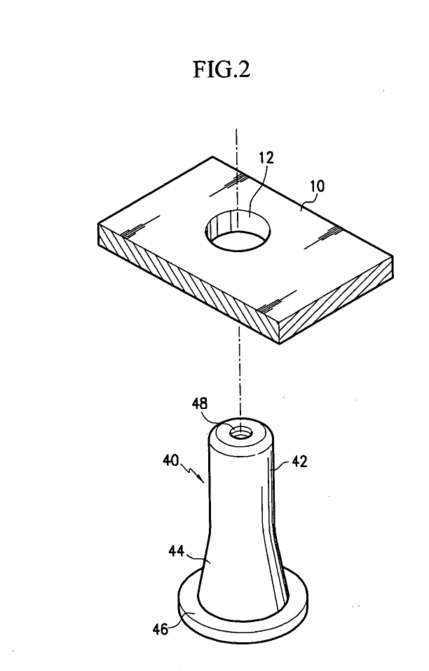

As shown in FIG. 2, the standoff 40 has a cylindrical portion 42 with an outer diameter smaller than the inner diameter of the combination hole 12, an inclined portion 44 extending from the cylindrical body 42 in a body with an outer diameter larger than the inner diameter of the combination hole 12, and a flange portion 46 connected to the inclined portion 44 in a body with an outer diameter larger than the outer diameter of the inclined portion 44.

An engagement or coupling hole 48 is formed within the standoff 40 to receive a bolt 32 for holding the driving module 30, as shown in FIG. 1 or other structural components, and a screw thread is formed at the coupling hole 48.

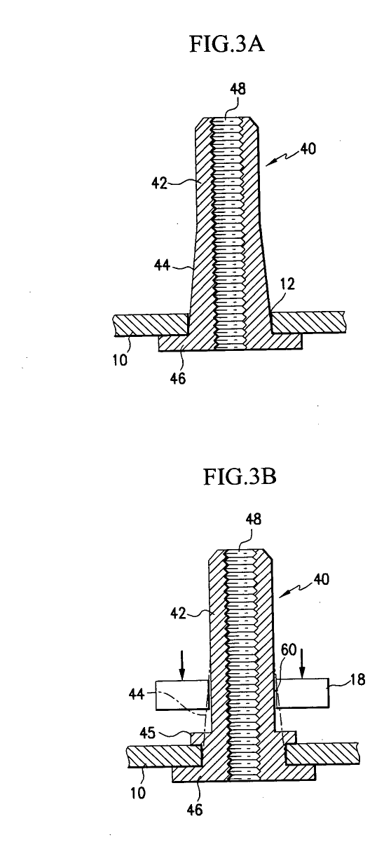

With the above-structured standoff 40, as shown in cross-section in FIG. 3A, the cylindrical portion 42 and the inclined portion 44 thereof are inserted into the combination hole 12 of the chassis base 10 such that a surface of the flange portion 46 is tightly adhered to a surface of the chassis base 10.

Thereafter, as shown in FIG. 3B, the inclined portion 44 is pressed and transformed using a separate tool, such as a die 18. In this process, the inclined portion 44 becomes a transformed portion 60 with an outer diameter substantially identical to the outer diameter of the cylindrical portion 42. At this time, a subsidiary flange portion 45 is formed together with the flange portion 46 wherein the flange portion 46 functions as a main flange relative to the subsidiary flange portion 45. The subsidiary flange portion 45 is press-fitted to the chassis base 10 such that the standoff 40 is rigidly fixed to the chassis base 10.

As described above, when the standoff 40 is fitted to the combination hole 12, the inclined portion 44 of the standoff 40 is changed into the transformed portion 60 and the subsidiary flange portion 45, and the subsidiary flange portion 45 is press-fitted to the chassis base 10 such that the standoff 40 is tightly adhered to the chassis base 10 at both sides of the base. Accordingly, the standoff 40 can exert enough supporting power to endure the live load.

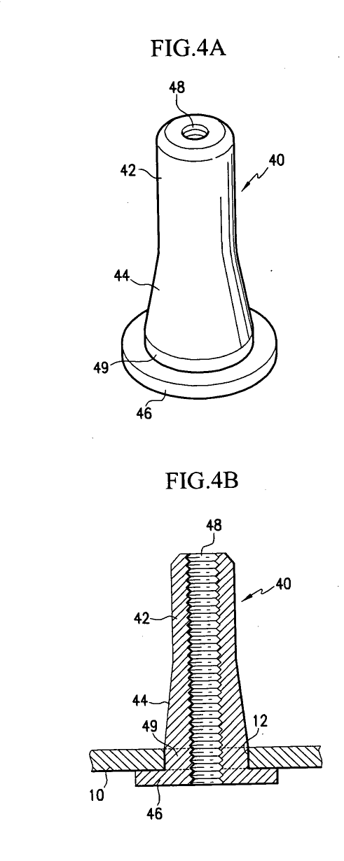

FIG. 4A is a perspective view of a standoff 40 for a plasma display device according to a second embodiment of the present invention. The basic structure of the standoff 40 of the second embodiment is the same as the structure of the first embodiment except that a reinforcing member 49 is further formed between the inclined portion 44 and the flange portion 46 with a cylindrical shape having an outer diameter identical with or slightly larger than the inner diameter of the combination hole 12 of the chassis base 10.

When the reinforcing member 49 is formed as described above and the standoff 40 is fitted to the combination hole 12, as shown in FIG. 4B, the reinforcing member 49 is inserted into the combination hole 12 or press-fitted thereto such that the combination of the standoff 40 with the chassis base 10 is reinforced.

In the process where the inclined portion 44 is pressurized by a die and changed into the transformed portion and the subsidiary flange portion (not shown), the reinforced combination state of the standoff 40 helps to prevent the standoff from vibrating and holds it at the precise location. In this way, the standoff 40 can be rigidly fitted to the combination hole 12.

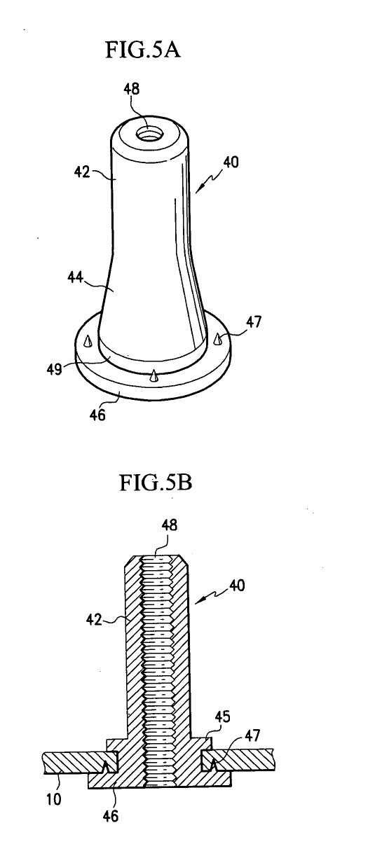

FIG. 5A is a perspective view of a standoff according to a third embodiment of the present invention. The basic structure of the standoff 40 is like the previous ones described. However, a plurality of fixation protrusions 47 are formed on the flange portion 46. The fixation protrusions 47 are tapered toward the chassis base 10 with a sharp end, and in this embodiment, shaped with a cone.

When the standoff 40 is fitted to the combination hole 12, as shown in FIG. 5B, the fixation protrusions 47 are inserted into the combination hole 12 while contacting a surface of the chassis base 10 to enhance the supporting power of the standoff 40 and to prevent it from being rotated.

The fixation protrusion 47 is not limited to the above shape. That is, the fixation protrusion 47 may be formed with a conical shape in its entire length, or with a cylindrical shape having a conical end portion.

Furthermore, the fixation protrusion 47 may be formed with a solid figure having a flat triangle, rectangle or other polygonal-shaped base with straight flat three-angled sides that slope upwards to meet at a point. The fixation protrusion 47 may also be elongated in the circumferential direction of the flange portion 46 or in the radial direction.

In an exemplary embodiment, two to eight fixation protrusions may be arranged around the flange portion 46 while being spaced apart from each other by a predetermined distance.

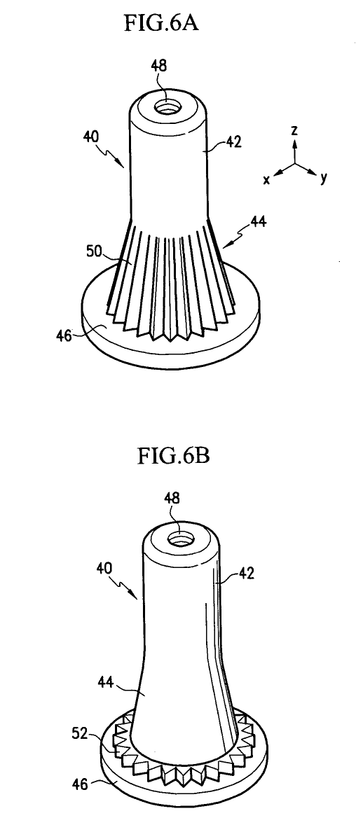

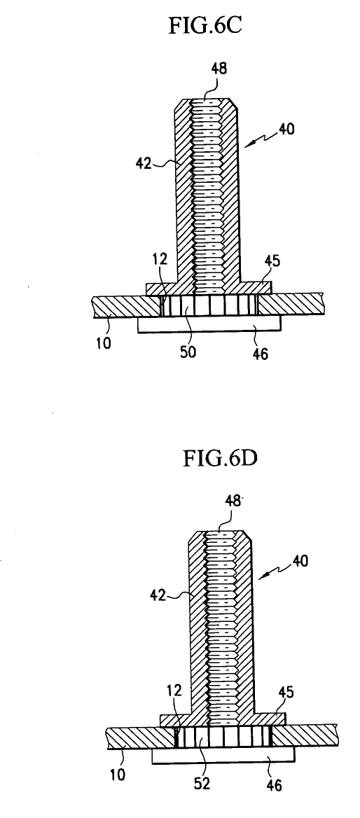

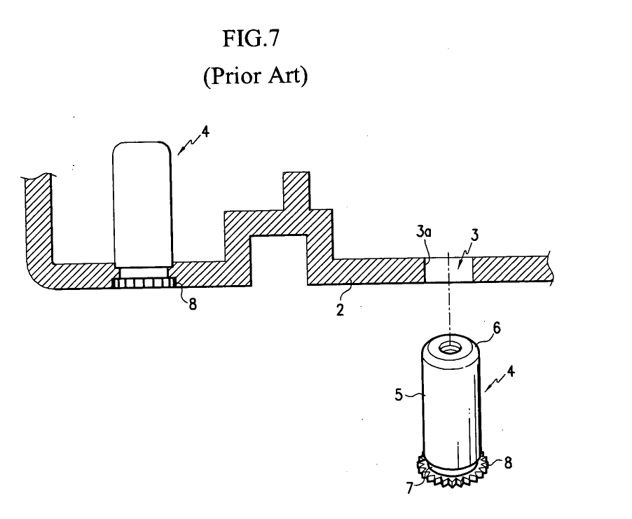

FIGS. 6A and 6B are perspective views of a standoff according to a fourth embodiment of the present invention. The basic structure of the standoff 40 is like that of the previous one described.

The standoff shown in FIG. 6A is provided with saw teeth 50 formed on the outer circumference of the inclined portion 44 while proceeding in a longitudinal direction (in the direction of the z axis of the drawing).

With the formation of saw teeth 50 on the inclined portion 44 of the standoff 40, when the standoff 40 is forcefully fitted to the combination hole 12 of the chassis base 10, or the inclined portion 44 is pressurized by a die to transform it into the subsidiary flange portion 45 (FIG. 6C), the saw teeth 50 are forced into the inner surface of the combination hole 12. Consequently, the standoff 40 is prevented from being rotated while becoming rigidly fixed to the chassis base, as shown in FIG. 6C.

Similarly, with the standoff 40 shown in FIG. 6B, a pressurization portion 52 is formed between the inclined portion 44 and the flange portion 46 with an outer diameter larger than the inner diameter of the combination hole 12. The outer circumference of the pressurization portion 52 is formed with a saw-toothed shape.

When the pressurization portion 52 is forcefully press-fitted into the combination hole 12 of the chassis base 10, it is forced into the inner surface of the combination hole 12 such that the standoff 40 is prevented from being rotated on the chassis base 10 while increasing the standoff's supporting power.

With the above-described structured plasma display device, when the standoff 40 is inserted into the chassis base 10, the inclined portion 44 is transformed such that the chassis base is press-fitted between the flange portion 46 and the subsidiary flange portion 45. In this way, the supporting power of the standoff is increased so as to be able to endure a live load.

Therefore, due to the packaging of the plasma display device, the device will not break, even under the application of a live load, enabling the reliable packaging of the device.

Furthermore, since the inclined portion 44 and the pressurization portion 52 of the standoff are saw-toothed and forced into the inner surface of the combination hole 12 of the chassis base 10 during press-fitting, the standoff is prevented from being rotated, and the standoff's 40 supporting power is sufficient even under the application of a twist load.

Because fixation protrusions are formed at the flange portion 46 of the standoff 40, the standoff is rigidly fixed to the chassis base, and prevented from being rotated.

As described above with respect to embodiments of plasma display device of the present invention, the structure of the standoff may be altered such that it can support a chassis base more rigidly. Even when a wall hanger is combined with the standoff, the standoff sustains enough supporting power to endure a live load.

Although exemplary embodiments of the present invention have been described in detail hereinabove, it should be clearly understood that many variations and/or modifications of the basic inventive concept herein taught which may appear to those skilled in the art will still fall within the spirit and scope of the present invention, as defined in the appended claims.

1. A plasma display device comprising:
a plasma display panel for displaying desired images;
a chassis base for supporting the plasma display panel, the chassis base having a plurality of combination holes; and
standoffs installed in the chassis base, each standoff having a cylindrical portion with an outer diameter, a transformed portion connected to the cylindrical portion with an outer diameter substantially identical to the outer diameter of the cylindrical portion and at least one flange connected to the transformed portion, and wherein the cylindrical portion and the transformed portion are inserted into the combination hole, and wherein the at least one flange is press-fitted to the surfaces of the chassis base while interposing the combination hole.

2. The plasma display device of claim 1, wherein the at least one flange is two flanges, a main flange and a subsidiary flange, the flanges facing each other with an outer diameter larger than the outer diameter of the cylindrical portion and the transformed portion, and wherein the flanges are press-fitted to the chassis base while interposing the chassis base.

3. The plasma display device of claim 1, further comprising a reinforcing member placed in the combination hole between the at least one flange with an outer diameter substantially identical with the inner diameter of the combination hole.

4. The plasma display device of claim 2, wherein a plurality of fixation protrusions are formed on the main flange to prevent the rotation of the standoff fitted to the chassis base.

5. The plasma display device of claim 4, wherein the fixation protrusions are tapered to a sharp end.

6. The plasma display device of claim 1, wherein a pressurization member is formed on the surface of the standoff facing the inner circumference of the combination hole to prevent the rotation of the standoff fitted to the chassis base.

7. The plasma display device of claim 6, wherein the pressurization member is formed with a saw-toothed shape.

8. The plasma display device of claim 1, wherein an engagement hole with an inner screw thread is formed within the standoff.

9. A standoff of a chassis base for a plasma display device, the standoff comprising:
a cylindrical portion with an outer diameter;
an inclined portion connected to the cylindrical portion with an outer diameter larger than the outer diameter of the cylindrical portion; and
a flange portion connected to the inclined portion with an outer diameter larger than the outer diameter of the inclined portion.

10. The standoff of claim 9, further comprising a reinforcing portion formed between the inclined portion and the flange portion, wherein the reinforcing portion has an outer diameter larger than the outer diameter of the cylindrical portion.

11. The standoff of claim 9, wherein a plurality of fixation protrusions are formed on the flange portion, wherein the fixation protrusions are tapered to a sharp end.

12. The standoff of claim 9, further comprising saw teeth formed around the inclined portion wherein the saw teeth extend along the longitudinal direction of the standoff.

13. The standoff of claim 9, further comprising a pressurization portion formed between the inclined portion and the flange portion, wherein the pressurization portion has a saw-toothed outer circumference.

14. The standoff of claim 9, wherein an engagement hole with an inner screw thread is formed within the standoff.
